(19) United States
(12) Patent Application Publication
(10) Pub. No.: US 2024/0110057 A1
(43) Pub. Date: Apr. 4, 2024

(54) Biodegradable Composite Material for Electronic Devices and Electrical Engineering

(71) Applicants: Dmitriy Khrustalev, Karaganda (KZ); Azamat Yedrissov, Karaganda (KZ)

(72) Inventors: Dmitriy Khrustalev, Karaganda (KZ); Azamat Yedrissov, Karaganda (KZ)

(21) Appl. No.: 18/220,830

(22) Filed: Jul. 12, 2023

(51) Int. Cl. C08L 67/04; H05K 1/03

(52) U.S. Cl. CPC C08L 67/04; H05K 1/036; C08L 2201/06

(57) ABSTRACT

The application describes a multilayer biodegradable electrically insulating composite material consisting of compressed layers of glass cloth or fiberglass pre-impregnated with a biodegradable polymer binder or alternately stacked layers of glass fiber and a polymer binder film. The developed material is close in its characteristics to the substrates of commercial printed circuit boards. Biodegradable electrically insulating composite material can be used as a substrate for creating single-sided or double-sided or multilayer printed circuit boards based on them, and can also be used to manufacture various electrical insulating materials and structures.

### CROSS-REFERENCE TO RELATED APPLICATIONS

Provisional patent 63/390,301. Filing date 07/19/2022.

### BACKGROUND OF THE INVENTION

### Field of the Invention

The present invention is directed to the field of creating a biodegradable electrical insulating composite material for electronic devices and electrical engineering, in particular, the present invention relates to the creation of a biodegradable electrical insulating composite material based on a biodegradable polymer: polylactic acid (L-PLA); or D-PLA; or mixtures thereof; or polyglycolic acid (as well as mixtures of polylactic and polyglycolic acids in any ratio) and fiberglass, for the manufacture of dielectric substrates for foiled printed circuit boards and various electrical insulating materials and structures.

### Description of the Related Art

The rapid growth in the use of electronic devices in various devices, both for household purposes (household electrical appliances, “Internet of things”, wearable communications) and the widespread use of electronic devices, for control, in various technological cycles at enterprises has led to a stable increase in the production of foil printed circuit boards (PCB) in the world, at the level of 3.1% per year [1]. However, therein lies the growing environmental problems associated with the disposal of an increasing number of obsolete electronic devices and PCBs. The problem is exacerbated by the fact that the life cycle of consumer electronic devices is rapidly shrinking. According to statistics [2], annually, in the world, up to 50 million tons of electronic wastes accumulate. Significant funds are needed for their burial, destruction or processing. In addition, environmental issues associated with the recycling of this type of electronic industry waste are of increasing concern in many countries around the world. Once in landfills, they litter the environment because they contain organic resins (phenolic, polyester, epoxy, and resole resins). The resulting toxins, mixing with groundwater, ultimately lead to long-term environmental pollution [1]. A PCB is an insulating plate that plays the role of a mechanical frame, on one or both surfaces to which a current conductor is applied, usually copper or aluminum foil. The insulating substrate of a PCB consists of a number of layers of fiberglass (fiberglass base laminate) or paper (paper base laminate) impregnated with thermosetting resins, which are pressed in thermal presses [3]. The problem of commercial PCB is the use of highly toxic substances to obtain a binder (epoxy and phenol-formaldehyde resin and mixtures thereof; combined organosilicon-epoxy resin; combined with epoxy-polyimide resin, bismaleimide resin, triazine resin; mixtures of the last 2 resins, etc.) [4]. The raw materials for the production of traditional binders are not formed from renewable sources, and PCB waste, based on them, pollutes the environment with toxic decomposition products. All this contradicts the modern requirements for the safety of chemical processes and materials, set out in the concept of “Green Chemistry” [5]. These circumstances led to an active search for ways to create biodegradable printed circuit boards [6-9]. In [6], methods were proposed for creating PCBs based on biodegradable polymers and lignin, which are mixed in a melt, then granules are formed from which PCB substrates are subsequently made. In [7], a method for the manufacture of biodegradable composites was proposed by mixing the components at a temperature of 155° C. and subsequently extrusion into sheets to form PCB, with electrically conductive tracks formed from a silver-based electrically conductive paste. In general, the methods for manufacturing biodegradable PCBs proposed in [6, 7] do not allow us to speak about the possibility of large-scale industrial production of such boards, and even less about replacing commercial PCBs, such as FR2 and FR4. Therefore, new types of biodegradable composite materials are needed that overcome the above disadvantages.

### REFERENCE

1. Globe Newswire. Available online: URL: https://www.globenewswire.com/news-release/2018/11/26/1656347/0/en/Global-Printed-Circuit-Board-PCB-Market-to-Witness-a-CAGR-of-3-1-during-2018-2024.html (2018).
2. Kaya, M. (2019). Electronic waste and printed circuit board recycling technologies. The Minerals, Metals & Materials Series. Springer, Cham.
3. U.S. Pat. No. 8,020,292B1.
4. U.S. Pat. No. 7,601,429B2.
5. Anastas, P. T. & Warner, J. C. (1998). Green Chemistry: Theory and Practice. Oxford University Press.
6. WO2013144420A1.
7. WO2015137922A1.
8. Khrustalev, D., Tirzhanov, A. et al. A new approach to designing easily recyclable printed circuit boards. Sci. Rep. 12, 22199 (2022).
9. Yedrissov, A., Khrustalev, D. et al. New composite material for biodegradable electronics. Materials Today: Proceedings. 49(6), 2443-2448 (2022).

### SUMMARY OF THE INVENTION

The aim of the present invention is to provide a biodegradable composite material having characteristics comparable to known commercial composite materials for the production of printed circuit boards. In addition, the resulting biodegradable composite material is capable of efficient chemical recycling, after which the components of the biodegradable composite are as reusable as possible.

### DETAILED DESCRIPTION OF THE INVENTION

The biodegradable composite material was obtained by us by thermal pressing of several layers of fiberglass, pre-impregnated with L-PLA, or D-PLA, or their mixture in various proportions, or polyglycolic acid. Fiberglass refers to both fiberglass yarns and fiberglass-based fabrics with any method of weaving threads. The mechanical properties of the resulting biodegradable composite varied depending on the number of fiberglass layers. Composite materials containing from 2 to 50 layers of fiberglass have been obtained. Next, copper or aluminum foil is applied to one or both sides of the resulting composite. Note that the electrical conductivity of copper foil is much higher than copper- and silver-containing conductive pastes [7]. Copper or aluminum foil can be applied to the surface of the obtained composite material in various ways, for example, by thermal pressing. The resulting biodegradable composite material is suitable for mechanical processing: drilling, sawing, milling and grinding. The manufacturing process of the biodegradable composite material was carried out under normal conditions on standard commercial equipment. PCB, based on biodegradable composite material, has characteristics close to commercial PCB. Values of volume resistivity, loss tangent values, dielectric permittivity, glass transition temperature, tensile strength, and bending strength of PCB based on the proposed composite are generally equal to those of commercial samples FR2 and FR4. The volume resistivity at 105 Hz of PCB based on the proposed composite is higher than the FR2 values and lower than the FR4 values. Loss tangent values at 105 Hz PCB based on the proposed composite are lower than FR2 and almost equal to FR4. The dielectric permittivity of PCB based on the proposed composite at 105 Hz is lower than that of commercial PCBs. The glass transition temperature of PCB based on the proposed composite is between FR2 and FR4. The ultimate tensile strength of PCB based on the proposed composite is higher than FR2 and practically equal to the ultimate tensile strength of FR4. The ultimate bending strength of PCB based on the proposed composite is lower than that of FR4 and equal to FR2.

It is possible to use chemical additives to the polymer matrix that increase various properties of the resulting composite, such as mechanical strength, heat resistance, fire resistance, adhesion to metal foil, etc. We also assume that the composite material developed by us can be used in other areas not listed by us.

### EXAMPLES

Example 1. A biodegradable composite material was made by thermal pressing from 2 to 50 layers of filler, pre-impregnated with a solution of a biodegradable polymer binder. The layers were pressed at a pressure of 50-50000 kPa and a temperature of 150-250° C. for 1-300 seconds. For the manufacture of PCB, aluminum or copper foil was applied to one or both sides of the composite material by thermal pressing. The binders used were: L-PLA or D-PLA or mixtures of L- and D-PLA or polyglycolide. Also, pure polyglycolic acid or mixtures thereof with any form of polylactic acid can be used as a polymeric matrix. Fiberglass was used as a filler in the form of individual fibers, as well as in the form of glass fiber. The copper foil 10-90 μm thick or aluminum foil 10-90 μm thick was used as the metal foil.

Example 2. A biodegradable composite material was produced by thermal pressing from 2 to 50 layers of filler and binder in the form of a film, folded alternately among themselves. The layers were pressed at a pressure of 50-50000 kPa and a temperature of 150-250° C. for 1-300 seconds. For the manufacture of PCB, one or both sides of the composite material, by thermal pressing, applied a metal foil. The binders used were: L-PLA or D-PLA or mixtures of L- and D-PLA or polyglycolide. Fiberglass was used as a filler in the form of individual fibers, as well as in the form of fiberglass. The copper foil 10-90 μm thick or aluminum foil 10-90 am thick was used as the metal foil. The thickness of the polymer binder film was 50-350 μm.

Example 3. Recycling PCB. The printed circuit boards, based on the biodegradable composite material as shown in examples 1 and 2, are recycled using an extraction process. The extraction process under conventional conditions, as well as under conditions of microwave, ultrasonic, electric pulse, sub-, and supercritical extraction, allows disassembling the composite material into its original components without damaging them. Effective extractants are organic and inorganic solvents, sub- and supercritical fluids, ion-exchange fluids, as well as individual chemicals.

A typical example of PCB recycling based on a biodegradable composite material is extraction recycling under ultrasonic cavitations conditions. PCB with soldered electronic components were immersed in a solvent such as ethyl acetate and placed in an ultrasonic bath. After treatment for 10-30 minutes at room temperature, the polymer matrix goes into solution. This method allowed complete separation of the polymer binder, copper tracks with electronic components and filler (fiberglass) from each other, without using additional manual, mechanical and thermal processes.

Copper conductors are separated from soldered electronic components such as microprocessors, microcontrollers, diodes, integrated circuits, capacitors, resistors, transformers, logic devices, coils, connector pins, batteries, antennas, LEDs, switches, and sensors using a heat gun and sent for recycling. Fiberglass and electronic components and polymer binder can be reused.

The effectiveness of the use of other extraction methods for the utilization of composite materials and electronic devices based on them has been established.

1. Biodegradable composite material for the manufacture of a dielectric substrate for printed circuit boards, made by thermal pressing of fiberglass layers pre-impregnated with a polymer binder solution, which is used as L-polylactic acid; or D-polylactic acid; or mixtures of L- and D-polylactic acids; or polyglycolic acid.

2. Biodegradable composite material for the manufacture of a dielectric substrate for printed circuit boards, made by thermal pressing of glass fiber layers and a polymer binder, which is used as L-polylactic acid; or D-polylactic acid; or mixtures of L- and D-polylactic acids; or polyglycolic acid, laid alternately in the form of a polymer film and a fiberglass cloth.

3. Recycling of biodegradable composite material and PCB based on it by separation into initial components, such as polymer binder, glass fiber, electronic components, and conductive paths, by extraction methods such as convection, ultrasonic, microwave, sub- and supercritical extraction, as well as electric pulse extraction with solvents organic, inorganic, sub- and supercritical fluids, ionic liquids, individual chemicals.
